(19) United States
(12) Patent Application Publication
(10) Pub. No.: US 2025/0391658 A1
(43) Pub. Date: Dec. 25, 2025

(54) INTEGRATED HIGH ASPECT RATIO ETCHING

(71) Applicant: Lam Research Corporation, Fremont, CA (US)

(72) Inventors: Zhongkui Tan, Fremont, CA (US); Xiaofeng Su, Fremont, CA (US); Yu Pan, San Jose, CA (US); Xiaolan Ba, Fremont, CA (US); Juwen Gao, San Jose, CA (US); Ming Li, West Linn, OR (US)

(21) Appl. No.: 18/877,839

(22) PCT Filed: Jun. 15, 2023
(86) PCT No.: PCT/US2023/025448

§ 371 Date: Dec. 20, 2024

Related U.S. Application Data
(60) Provisional application No. 63/367,121, filed on Jun. 27, 2022.

(51) Int. Cl. H01L 21/033; H01L 21/311

(52) U.S. Cl. CPC H01L 21/0332; H01L 21/0335; H01L 21/31122; H01L 21/31144

(57) ABSTRACT

Methods for etching features into carbon material using a doped tungsten-containing mask, such as a boron-doped tungsten material. to reduce and eliminate redeposition of silicon-containing residues are provided herein. Methods involve de-positing a doped tungsten-containing material over the carbon material prior to etching the carbon material, patterning the doped tungsten-containing material to form a doped tungsten-containing mask, and using the patterned doped tungsten-containing mask to etch the carbon material such that the use of a silicon-containing mask during etch of the carbon material is eliminated.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor fabrication processes often involve etching carbon-containing material using a mask. However, as devices shrink, and technology advances, it is challenging to etch carbon-containing materials using existing hard masks without affecting the profile of the pattern to be etched into the carbon-containing materials.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method including: providing a substrate including an amorphous carbon layer to be etched, the amorphous carbon layer having a thickness of at least about 100 nm; forming a patterned doped tungsten-containing mask over the amorphous carbon layer; and etching the amorphous carbon layer using the patterned doped tungsten-containing mask to form a patterned carbon-containing layer.

In various embodiments, the patterned doped tungsten-containing mask includes a metal dopant, the metal dopant such as one of boron, titanium, tungsten, tantalum, tin, aluminum, and combinations thereof. In some embodiments, the metal dopant includes or is boron.

In various embodiments, the amorphous carbon layer is dopant-free.

In various embodiments, the amorphous carbon layer includes less than about 10% impurities.

In various embodiments, the method also includes, prior to forming the patterned doped tungsten-containing mask, depositing an adhesion layer directly on the amorphous carbon layer. In some embodiments, the adhesion layer includes tungsten and nitrogen.

In various embodiments, the patterned doped tungsten-containing mask is silicon free.

In various embodiments, forming the patterned doped tungsten-containing mask includes depositing doped tungsten-containing material and etching the doped tungsten-containing material using a photoresist mask to form the patterned doped tungsten-containing mask.

In various embodiments, dopant concentration of the metal in the patterned doped tungsten-containing layer is about 20% to about 60%.

In various embodiments, etch rate of the amorphous carbon layer is at least about three times faster than etch rate of the patterned doped tungsten-containing layer when etching the amorphous carbon layer.

In various embodiments, ratio of thickness of the patterned doped tungsten-containing mask to thickness of the amorphous carbon layer is about 1:5 to about 1:30. In some embodiments. the etching of the patterned doped tungsten-containing mask is performed using a bias. For example, in some embodiments, the bias power is at least about 1000V.

In various embodiments, ellipticity of features formed in the amorphous carbon layer after the etching the amorphous carbon layer is about 1 to about 1.1.

In various embodiments, the etching of the amorphous carbon layer is performed using one or more gases that form volatile byproducts with the patterned doped tungsten-containing mask and amorphous carbon layer without redepositing material onto substrate surfaces.

In various embodiments, the patterned doped tungsten-containing mask is etched to form features having a critical dimension about 50 nm to about 500 nm.

In various embodiments, the patterned doped tungsten-containing mask is doped with boron and the etching of the amorphous carbon layer is performed in a silicon-free environment.

These and other aspects are described further below with reference to the drawings.

### BRIEF DESCRIPTION OF THE DRAWINGS

FIGS. 1A-1C provide schematic illustrations of a substrate undergoing etching operations.

FIG. 2 is a process flow diagram depicting operations performed in accordance with certain disclosed embodiments.

FIGS. 3A-3D are schematic illustrations of substrates undergoing operations of certain disclosed embodiments.

FIG. 4 is a schematic diagram of an example process chamber for performing certain disclosed embodiments.

FIG. 5 is a schematic diagram of an example process apparatus for performing certain disclosed embodiments.

FIG. 6 is a graph showing relative etch rates of doped tungsten-containing material and silicon nitride in accordance with certain experiments.

FIG. 7 is a graph showing relative etch rates of doped tungsten-containing material and silicon nitride in SiON etch chemistry in accordance with certain experiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes involve fabrication of memory and logic devices. Examples include 3D NAND and dynamic random-access memory (DRAM) applications, as well as logic applications for mid end of line (MEOL) and back end of line (BEOL) processes. Fabrication of memory and logic devices often involve etching features, such as contact holes, on a substrate, which may include one material or multiple layers of material some of which may be semiconductor material. “Features” such as via or contact holes may be characterized by one or more of narrow and/or re-entrant openings, constrictions within the feature, and high aspect ratios. The term “feature” as described herein refers to negative features such as holes or vias. Etching features, in many cases, involves depositing and patterning a hard mask over the material to be etched, and etching the material using the hard mask as a pattern. The patterned hard mask may eventually be removed from the substrate.

Some fabrication methods of semiconductor devices involve etching of an amorphous carbon material using a hard mask. As devices shrink, some amorphous carbon material that is etched using a hard mask are very thick, such as having a thickness of at least 0.1 μm, at least 0.5 μm, at least 1 μm, or at least about 2 μm, or at least about 3 μm, or at least about 4 μm, or greater than 4 μm. It may be difficult to transfer patterns to thick layers of amorphous carbon for certain applications having many NAND layers in 3D-NAND fabrication, such as at least 90 NAND layers or more. Additionally, because the amorphous carbon material is very thick, features formed in them may have high aspect ratios, such as at least about 25:1, or at least about 30:1, or at least about 40:1, or at least about 50:1. Other challenges include maintaining etch selectivity, maintaining etch profile (such as bowing issues and critical dimension issues, which may also cause problems at a bottom of a stack), local critical dimension uniformity (LCDU), ellipticity (hole major diameter divided by minor diameter), and other issues. It may be more difficult to control such properties during etching of various substrates due to these challenges. Such issues may lead to electrical failure at the memory string level, which is related to device performance.

Mask selectivity is a particular challenge when the stack is thicker. For example, it may be more challenging to etch memory holes, slits, contact holes, and other features. For example, in an ONON (oxide-nitride-oxide-nitride) or OPOP (oxide-polysilicon-oxide-polysilicon) stack of at least 6 μm, an amorphous carbon layer may have a thickness of greater than about 3 μm. To etch such thick layers, the hard mask must likewise be thick; for example, hard masks over the amorphous carbon layer may be at least about 250 nm thick. The thickness of both the hard mask and the amorphous carbon layer results in an extremely high aspect ratio feature to be etched, and as noted below, sputtered mask materials and redeposition of silicon-containing materials may cause clogging at the top of the feature.

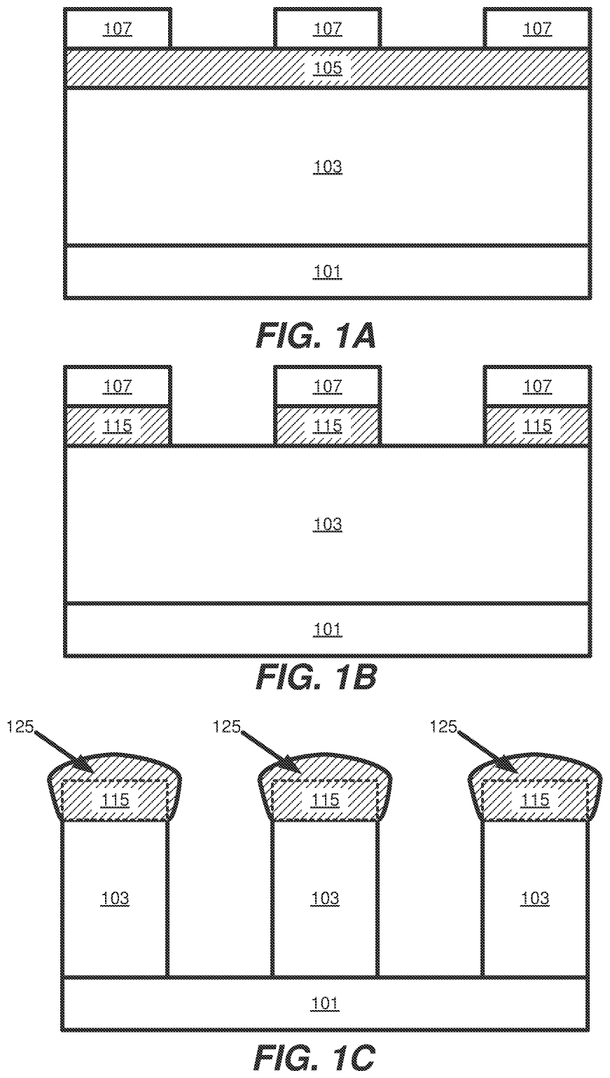

In some methods, a silicon-containing hard mask is used as a mask when etching amorphous carbon. For example, a silicon oxynitride, silicon nitride, silicon, or silicon oxide hard mask may be used. An example is provided in FIG. 1A, which shows a substrate 101 having an amorphous carbon layer 103, a silicon oxynitride hard mask 105, and patterned photoresist 107. While FIG. 1A only shows amorphous carbon layer 103, silicon oxynitride hard mask 105, and patterned photoresist 107, it will be understood that various other layers may also be present on the substrate, such as but not limited to anti-reflective coatings, spin-on films, and other barrier, adhesion, and/or intermediate layers.

In various embodiments, the patterned photoresist 107 is formed by depositing photoresist material, such as carbon-containing material, and developing the photoresist material using photolithography techniques.

In FIG. 1B, the silicon oxynitride hard mask 105 is etched using the pattern of the patterned photoresist 107 to form patterned silicon oxynitride hard mask 115. In FIG. 1C, the amorphous carbon layer 103 is etched using the pattern of the patterned silicon oxynitride hard mask 115. However, because the amorphous carbon layer 103 is exposed to etchants for a long duration using etch chemistries that may form non-volatile byproducts with silicon, non-volatile etch residues 125 (such as silicon oxide residues) and silicon etching byproducts may redeposit onto the tops or near the openings of the features in the patterned silicon oxynitride hard mask 115, which reduces and affects the critical dimension of features between the etched amorphous carbon 113. Redeposition may result in increased thickness of up to 20 nm on the sidewalls of the features, which in various embodiments may be thick enough to close off the entire feature opening. This may occur while some thickness of silicon oxynitride hard mask 115 remains on the substrate, the thickness of which may be slightly reduced due to some etching of the silicon oxynitride hard mask 115 by the etchants. This results in critical dimension variation of features across the wafer.

As shown, the presence of silicon in the hard mask during etching of the amorphous carbon material may cause degradation resulting in increased local critical dimension variation. Some of these methods may result in mask faceting, ellipticity of features, line width roughness, space width roughness, and feature twisting.

Ellipticity of features is measured by dividing the major diameter by the minor diameter. A perfectly circular feature will have an ellipticity of 1. The redeposition of silicon-containing materials onto tops of features can cause the ellipticity of features to be about 1.16 or greater. However, using certain disclosed embodiments described herein, ellipticity of features may be between about 1 to about 1.3.

Variation of critical dimension in one direction can cause feature twisting, which can ultimately result in a short or etching issues later on. For example, undesirable high critical dimension variation can result in an unopened ONON gate edge after opening the mask, thereby causing issues on the device.

In some methods, etching using a silicon-containing hard mask results in redeposition of non-volatile silicon or silicon-containing etch residues, such as silicon oxide residues, at or near feature openings, thereby degrading the profile of the features to be etched and causing defects on the substrate. In some embodiments, the silicon oxide residue buildup may be so large so as to completely close the feature, rendering the substrate useless. Such processes may result in reduced or limited device performance, or yield loss of devices.

Provided herein are methods and apparatuses for etching amorphous carbon material with while maintaining etch selectivity, ellipticity, critical dimension uniformity, and feature profiles. Certain disclosed embodiments involve using a doped tungsten-containing hard mask in lieu of a silicon-containing hard mask over an amorphous carbon layer, the doped tungsten-containing hard mask providing robust properties and being silicon-free to ensure etching of the amorphous carbon layer is performed without redeposition at or near the feature opening.

Without being bound by a particular theory, it is believed that the presence of the dopant in the tungsten-containing layer helps facilitate etch selectivity. Where a silicon-containing hard mask is used, silicon builds up on sidewalls of the features, redepositing onto about 30% to about 50% of the sidewall surface. Where an elemental boron hard mask is used, less than about 1% boron is built up on sidewall surfaces. However, boron has a smaller atomic number, and being lightweight, it can cause sputtering, resulting in high sputter yield. As a result, during etching of the amorphous carbon material, boron loss is high, and the thickness of an elemental boron hard mask is much thicker to accommodate the duration of etching to sufficiently etch a very thick amorphous carbon material. Metal-containing hard masks have an advantage of achieving high selectivity, and while some may form polymers on the sidewall, the incorporation of a dopant helps reduce the polymerization, thereby combining the synergistic effect of both reducing redeposition on sidewalls of the feature and having robust etch selectivity.

Doped tungsten-containing hard masks also have a higher atomic number for tungsten than for silicon, higher film density, and higher modulus. The higher atomic number may improve the etch selectivity relative to the carbon material as compared to silicon-containing hard masks. The metal dopants allow the metal film to reduce its crystalline structure and improves etch selectivity and reduces clogging. Doped tungsten-containing hard masks can be deposited by thermal chemical vapor deposition (CVD) or thermal atomic layer deposition (ALD) or other similar techniques. The film stress of the doped tungsten-containing hard mask may be tuned by modulating one or more process conditions during deposition, such as but not limited to gas flow, pressure, and deposition temperature. Tuning stress minimizes the impact that the shape of the pattern has on the etching (such as reducing line bending), minimizes the changing of the shape of the feature holes during etching, and results in better pattern transfer.

Certain disclosed embodiments are suitable for patterning schemes including but not limited to self-aligned double patterning and self-aligned quad patterning schemes. In various embodiments, the presence of tungsten in the mask may help reduce the formation of facets in the patterned mask, and when patterning the underlying carbon material.

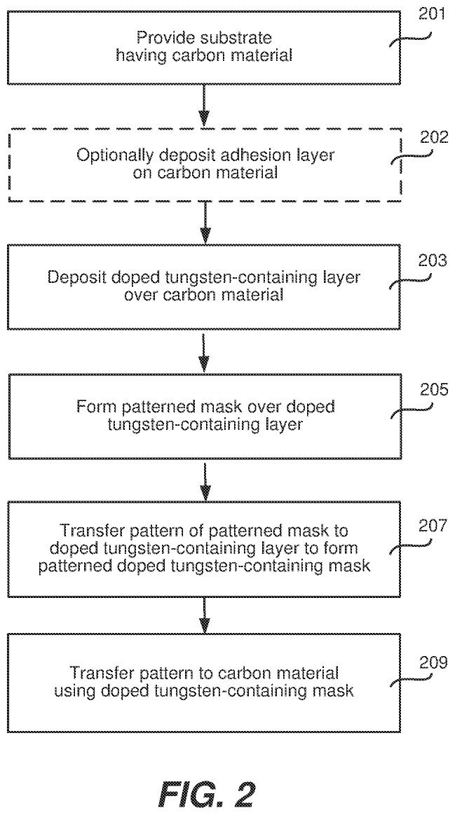

FIG. 2 is a process flow diagram showing an example method for performing operations in accordance with certain disclosed embodiments. In operation 201, a substrate having a carbon material is provided. The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. The feature(s) may be formed in one or more of the above described layers. In some embodiments, a feature may be formed on one or more of the top most layers of a substrate such that the bottom of the feature is an exposed underlayer. One example of a feature is a pillar or pole in a semiconductor substrate or a layer on the substrate. Another example is a trench in a substrate or layer. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

In various embodiments, the substrate is a blanket layer. In various embodiments, the substrate includes carbon material such as amorphous carbon material. The amorphous carbon material may be referred to herein as an “amorphous carbon layer” or “ACL.” The amorphous carbon material may be a blanket layer having no features etched thereon. In many embodiments, carbon material has a metal content of 0%. In various embodiments, the amorphous carbon material is metal-free. In various embodiments, the amorphous carbon material may be the material to be ultimately etched after forming appropriate hard masks over it with the desired pattern. The carbon material is substantially dopant-free, which is defined such that a substantially dopant-free carbon material includes materials with very low amounts of dopant, such as having a dopant concentration in the carbon material less than about 1%, or about 0%, or 0%. In various embodiments, the amorphous carbon layer is tungsten-free. In various embodiments, the amorphous carbon material is boron-free. In some embodiments, the carbon material includes trace amounts of hydrogen and/or nitrogen. In various embodiments, the amorphous carbon layer includes trace amounts of hydrogen, such as less than about 1% of hydrogen, or about 0% of hydrogen. In various embodiments, the amorphous carbon layer includes trace amounts of nitrogen, such as less than about 1% of nitrogen, or about 0% of nitrogen. In some embodiments, the amorphous carbon material has less than about 40% non-carbon atoms, or less than about 30% non-carbon atoms, or less than about 15% non-carbon atoms.

The amorphous carbon material may also vary in hardness such as material having a hardness between about 8 and about 12. The amorphous carbon material may also have certain modulus, such as between about 60 GPa and about 160 GPa. In some embodiments, the percentage of sp3 bonds in the amorphous carbon material may be between about 15% and about 50%.

In various embodiments, thickness of the amorphous carbon material is at least about 50 nm, or at least about 200 nm, or at least about 300 nm, or at least about 500 nm, or at least about 1000 nm, or at least about 1500 nm, or at least about 2000 nm, or at least about 3000 nm, or at least about 5000 nm, or at least about 7000 nm, or about 50 nm to about 1000 nm, or about 50 nm to about 8000 nm.

The critical dimension of features to be etched in the amorphous carbon material depends on the application. In some embodiments, the features have a critical dimension of at least about 50 nm, or at least about 80 nm, or at least about 100 nm, or about 50 nm to about 500 nm for 3D-NAND applications. In some embodiments, the features have a critical dimension of at least about 10 nm, or at least about 15 nm, or at least about 20 nm, or about 16 nm to about 22 nm for DRAM applications.

Features on the substrate provided may have multiple different sizes. In some embodiments, the substrate may include features with large feature openings, features with small feature openings, features with high aspect ratios, features with small aspect ratio features, or combinations thereof.

Returning to FIG. 2, in an operation 202, an adhesion layer is optionally deposited on the amorphous carbon material. In some embodiments, the adhesion layer may include some nitrogen atoms. In some embodiments, nitrogen atoms in the adhesion layer may diffuse into the tungsten-containing layer later deposited in an operation 203 further described below.

In some embodiments, the adhesion layer is a tungsten-containing layer. Examples compositions of the adhesion layer include but are not limited to tungsten nitride, titanium nitride, tungsten carbide, tungsten carbonitride, and tungsten. In some embodiments, the adhesion layer is doped with a dopant. In some embodiments, the dopant is boron. The adhesion layer is deposited at a temperature of at least about 325° C.

The adhesion layer may be deposited to a thickness of at least about 2 nm in thickness. In some embodiments, the adhesion layer may be deposited to a thickness of at least about 5 nm in thickness. In some embodiments, the adhesion layer may be deposited to a thickness of about 2 nm to about 5 nm. Certain thicknesses may be suitable for forming at least about 100 nm of doped tungsten material in subsequent operations. In some embodiments, the adhesion layer may be used to facilitate nucleation of tungsten-containing film grains on the amorphous carbon material surface in subsequent embodiments. In some embodiments, a soak operation may be performed prior and in addition to or in lieu of deposition of an adhesion layer. For example, in some embodiments, the amorphous carbon layer may be exposed to a diborane (B₂H₆) soak prior to depositing the adhesion layer, or may be exposed to a diborane soak without depositing the adhesion layer, such that performing the soak allows nucleation of the tungsten-containing material in subsequent operations. In some embodiments, the soak and/or adhesion layer deposition may reduce or eliminate nucleation delay when depositing the tungsten-containing material.

In some embodiments, deposition at higher temperature may result in better adhesion. In some embodiments, deposition using an increased flow of diborane may result in better adhesion.

In some embodiments, the adhesion layer is deposited in a plasma-free deposition process. In some embodiments, the adhesion layer is deposited thermally. In some embodiments, the adhesion layer is deposited by CVD or ALD or by another deposition technique.

ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optional generation of a plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of tungsten nitride films, this reaction may involve reacting a tungsten-containing precursor gas with a nitrogen-containing gas in temporally alternating pulses. In ALD deposition of tungsten nitride films, a ternary reaction may be used. For example, one non-limiting ternary reaction example may involve pulsing diborane, purging, pulsing tungsten hexafluoride, purging, and pulsing with ammonia.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a tungsten-containing precursor may include the tungsten-containing precursor as well as derivatives of the tungsten-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an nitrogen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

In an operation 203, a doped tungsten-containing layer is deposited over the carbon material. While operations in FIG. 2 may be performed in any order, in some embodiments, operation 202 may be performed prior to operation 203 such that the doped tungsten-containing layer in operation 203 is deposited on the adhesion layer deposited in operation 202. In various embodiments, the doped tungsten-containing layer is deposited directly on the carbon material without depositing an adhesion layer. In various embodiments, the doped tungsten-containing layer is deposited directly on the carbon material after the carbon material is exposed to a diborane soak. In various embodiments, the doped tungsten-containing layer is deposited directly on the adhesion layer such that the adhesion layer is sandwiched between the doped tungsten-containing layer and the carbon material.

In various embodiments, the metal dopant of the doped tungsten-containing layer may be boron. In some embodiments, the metal dopant may be any one or more of the following metals: boron, phosphorous, nitrogen, carbon, and chlorine. In various embodiments, the metal dopant may depend on what metal is used, what precursor is used, and other process conditions. In some embodiments, the doped tungsten-containing layer is boron-doped tungsten.

The amount of metal dopant in the doped tungsten-containing layer may be at least about 15% atomic, or at least about 20% atomic, or at least about 30% atomic, or at least about 40% atomic, or at least about 50% atomic, or about 60% to about 70% atomic, or up to about 80% atomic, or about 20% to about 50% atomic. In some embodiments, the amount of boron in the doped tungsten-containing layer may be at least about 15% atomic, or at least about 20% atomic, or at least about 30% atomic, or at least about 40% atomic, or up to about 50% atomic, or about 20% to about 50% atomic. In some embodiments, over 50% atomic composition of a boron dopant in tungsten specifically may cause deformity in the film. For example, in some embodiments, a high amount of boron may reduce wafer bowing, but non-uniformity may occur; however, in various embodiments, non-uniformity may be due to hardware or other factors and may be mitigated. In some embodiments, with other metal-containing layers that may be deposited, having a boron dopant concentration of up to about 80% can result in additional benefits for improving etch selectivity and other properties. The amount of metal dopant can be varied by modulating process conditions. For example, in some embodiments, increasing temperature may increase dopant concentration. In some embodiments, increasing exposure time to the tungsten-containing precursor used to deposit the doped tungsten-containing layer in an ALD cycle may reduce dopant concentration. In some embodiments, increasing flow rate of one or more process gases may increase dopant concentration. In some embodiments, modulating relative flow rates of process gases and partial pressures of gases in vapor phase may be used to modulate the dopant concentration. For a CVD reaction, increasing chamber pressure may increase deposition rate; for example, higher chamber pressure may result in more residual gas in a processing region above the substrate surface such that additional metal may be deposited.

The doped tungsten-containing layer may be deposited by CVD or by ALD. In some embodiments, the doped tungsten-containing layer is deposited in a plasma-free environment.

The doped tungsten-containing layer is amorphous. The metal dopant is used to achieve an amorphous film as an elemental tungsten film may have more of a crystalline structure.

The doped tungsten-containing layer is deposited to a thickness sufficient to withstand subsequent etching operations used to etch the carbon material. For example, in some embodiments, the doped tungsten-containing layer is deposited to a thickness of at least about 10 nm, or at least about 50 nm, or at least about 100 nm, or at least about 200 nm, or about 10 nm to about 300 nm.

Stress of the doped tungsten-containing layer may be modulated by modulating a variety of deposition process conditions during operation 203, including but not limited to gas flow, pressure, and deposition temperature.

In various embodiments, operation 203 may be performed at a substrate temperature of at least about 200° C., or at least about 300° C., or about 300° C. to about 350° C. The deposition rate of the doped tungsten-containing layer and the dopant concentration formed in the doped tungsten-containing layer may vary depending on the temperature of the substrate during deposition. For example, a higher temperature may result in a higher concentration of dopant in the doped tungsten-containing layer. In one example, a higher temperature may result in a higher concentration of boron in the doped tungsten-containing layer.

In an example where doped tungsten-containing layer is deposited by ALD, the substrate is exposed to a “dose” whereby a tungsten-containing precursor is introduced in vapor phase to the substrate surface, thereby causing at least one tungsten-containing precursor to be adsorbed onto a surface of the substrate. The tungsten-containing precursor may be a halogen-containing precursor, such as tungsten hexafluoride, tungsten pentafluoride, tungsten hexachloride, or tungsten pentafluoride. In some embodiments, the tungsten-containing precursor may be an organometallic tungsten precursor. The “dose” may be performed for a duration of about 0.1 seconds to about 30 seconds.

After the “dose,” the tungsten-containing precursor gas flow is stopped or diverted, and the process chamber may be optionally purged to remove any excess tungsten-containing precursor gas molecules in the processing region above the substrate surface. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, purging may include one or more evacuation subphases for evacuating the process chamber. Alternatively, it will be appreciated that purging may be omitted in some embodiments. Purging may have any suitable duration, such as between about 0 seconds and about 60 seconds, for example about 0.01 seconds or for example about 100 ms.

Following an optional purging operation, a “conversion” operation may be performed such that a second reactant is introduced to react with the adsorbed tungsten-containing precursor to form a tungsten-containing material on a surface of the substrate. The second reactant may include a dopant. In some embodiments, the second reactant is a boron-containing reactant, such as diborane. In some embodiments, the second reactant is a nitrogen-containing reactant, such as ammonia. In some embodiments, the second reactant is a hydrogen-containing reactant, such as ammonia. In some embodiments, the second reactant includes one or more gases, such as diborane, ammonia, hydrogen, and combinations thereof. In various embodiments, the second reactant reacts with the adsorbed tungsten-containing precursor in a thermal and/or plasma-free reaction such that no plasma is ignited or no plasma species are in the processing region above the substrate during the operation. One or more inert gases and/or carrier gases may also be flowed concurrently or may be flowed with the second reactant then diverted prior to delivery to the showerhead of the process chamber.

Following a “conversion” operation, a second optional purging may be performed. The overall process including a “dose” and “conversion” may be performed in any order (for example, the tungsten-containing precursor may be introduced, followed by the second reactant; or the second reactant may be introduced, followed by the tungsten-containing precursor). In some embodiments, an overall ALD cycle may include at least one dose and one conversion operation. In some embodiments, an overall ALD cycle may include a dose, a purge, a conversion, and a second purge. Multiple ALD cycles may be performed to build film thickness.

In some embodiments, the doped tungsten-containing layer in operation 203 is deposited by thermal CVD. In thermal CVD, the substrate is exposed to one or more tungsten-containing precursor gases and a second reactant such that the tungsten-containing precursor gas and second reactant react to form a doped tungsten-containing layer. In some embodiments, the reaction occurs in the processing region above the substrate. In some embodiments, the reaction occurs on the substrate surface to form tungsten-containing material on the substrate surface.

Deposition time may also affect the dopant concentration in the doped tungsten-containing layer. For example, a longer deposition time will result in a higher dopant concentration.

Deposition flow for the reactants used, particularly the dopant-containing reactant, also affects the dopant concentration. For example, an increased flow rate of the dopant-containing reactant will result in a higher dopant concentration in the doped tungsten-containing layer.

Pressure may also affect the dopant concentration, or the deposition rate, or both. For example, in a CVD-based deposition process, increased pressure may increase the reaction rate between the tungsten-containing precursor and the dopant-containing reactant and increase the deposition rate. Additionally, relative partial pressure of various gases used during deposition also affects dopant concentration. For ALD processes, increased pressure may result in more ambient material in the processing region when the dopant-containing reactant is introduced and may result in more deposition. For example, an incomplete purge after introducing tungsten hexafluoride might result in more tungsten deposition when the diborane is later introduced. In some embodiments, the flow ratio of tungsten-containing precursor to dopant-containing reactant may affect the dopant concentration.

The ratio of the thickness of the doped tungsten-containing layer to the thickness of the carbon material may be between about 1:5 and about 1:30. In various embodiments, the doped tungsten-containing layer is deposited directly on the carbon material.

The doped tungsten-containing layer is silicon-free. Doped tungsten-containing hard masks include tungsten atoms, which may be cross-linked. In some embodiments, doped tungsten-containing hard masks having boron include cross-linking between tungsten boride and additional tungsten and boron atoms, or between tungsten boride and additional tungsten atoms, or between tungsten boride and additional boron atoms. The different types of cross-linking observed in a doped tungsten-containing layer depends on the process conditions for depositing the layer, such as deposition precursor chemistry, temperature, chamber pressure, and plasma conditions.

In one example, at least about 100 nm of boron-doped tungsten is deposited by reacting tungsten hexafluoride with diborane over about 5 nm of adhesion layer formed on a very thick amorphous carbon layer.

Returning to FIG. 2, in an operation 205, a patterned mask is formed over the doped tungsten-containing layer. In some embodiments, the patterned mask is a patterned photoresist. A patterned photoresist may be formed by depositing a photoresist layer and lithographically patterning the photoresist. In some embodiments, prior to forming the patterned mask, a bottom anti-reflective coating layer is formed over the doped tungsten-containing layer. In some embodiments, the bottom anti-reflective coating (BARC) layer may be a polymeric material, such as one having a chemical formula CₓH_{y}O_{z}. In some embodiments, the BARC layer has a thickness of about 10 nm to about 50 nm. In some embodiments, the BARC layer may be deposited by spin-on methods. In some embodiments, the patterned mask formed over the doped tungsten-containing layer includes both a patterned BARC layer and a patterned photoresist. In one non-limiting example, the BARC layer can be patterned by using a CFₓ compound, such as CF₄, and a plasma, where power may be pulsed alternately at a frequency of about 200 Hz. The flow rate of CF₄ may be between about 50 sccm and about 200 sccm. Other gases that may be pulsed in this step include helium (He).

Returning to FIG. 2, in an operation 207, the pattern of the patterned mask is transferred to the doped tungsten-containing layer to form a patterned doped tungsten-containing mask. Transfer of the pattern to the doped tungsten-containing layer may be performed by etching the doped tungsten-containing layer using the patterned mask as a mask. The mask may be etched using a halogen-containing etching species. Example halogen-containing gases used include, but are not limited to, chlorine, fluorine, nitrogen trifluoride, and boron trifluoride. In various embodiments, the etching is selective to the underlying carbon material so as not to etch the carbon material while forming the patterned doped tungsten-containing layer. In some embodiments, this operation also includes etching the optional adhesion layer to expose the surface of the carbon material. One skilled in the art will recognize that the actual species present in the plasma may be a mixture of different ions, radicals, and molecules derived from the etching gases. It is noted that other species may be present in the reaction chamber during the removal of the doped tungsten-containing material, such as the volatile by-products as the plasma reacts with and breaks down the doped tungsten-containing material. The initial one or more gases introduced into the plasma may be different from the one or more gases that exist in the plasma as well as the one or more gases that contact the surface of the substrate during etching. Various types of plasma sources may be used including RF, DC, and microwave based plasma sources. In some embodiments, an RF plasma source is used. Typically, the RF plasma power for a 300 mm wafer ranges between about 500 W and about 10000 W, or between about 3000 W and about 10000 W. In some embodiments, the power is about 7000 W per station. Depending on the process chamber being used, in some embodiments, each station has a dedicated power source. In various embodiments, the plasma is generated as an inductively coupled plasma upstream of the showerhead. In various embodiments, a bias is not applied to the pedestal during etching of the metal doped carbon containing material. However, in some embodiments, an RF bias is used. An RF bias may be used in some embodiments. Various types of RF biases may be used; for example, RF bias may be generated at a frequency of 13.56 MHz, or lower, including but not limited to 400 MHz, 2 MHz, and 1 MHz. An example of a high bias is a bias having a power of at least about 1000V applied to the pedestal during etch. The use of a bias depends on the chemistry and whether directional etching is used in the application of using certain disclosed embodiments.

If a bias is applied, the power applied to the bias may be between about 10V and about 3000V, such as about 10V. It will be understood that the terms “bias power” and “bias voltage” are used interchangeably herein to describe the voltage for which a pedestal is set when a bias is applied to the pedestal. Bias power or bias voltage as described herein is measured in watts for the power applied to the pedestal. Pulsed bias may be used in some embodiments to prevent etching of the silicon-containing patterned mask. A pulsed plasma may be pulsed between a low and high bias, or between a bias in the ON state and a bias in the OFF state (0V) state. Pulsing between a low bias and a high bias involves pulsing between a low bias between about 100V and about 300V and a high bias between about 1000V and about 2500V. Pulsing may be performed using a duty cycle between about 3% and about 40%, or about 3% to about 99%, or 100% (continuous bias). Duty cycle refers to the duration the pulse is on during a period. It will be understood that bias pulsing may involve repetitions of periods, each of which may last a duration T. The duration T includes the duration for pulse ON time (the duration for which the bias is in an ON state) and the duration for bias OFF time (the duration from which the bias is in an OFF state) during a given period. The pulse frequency will be understood as 1/T. For example, for a bias pulsing period T =100 μs, frequency is 1/T=1/100 μs, or 10 kHz. The duty cycle or duty ratio is the fraction or percentage in a period T during which the bias is in the ON state such that duty cycle or duty ratio is pulse ON time divided by T. For example, for a bias pulsing period T=100 μs, if a pulse ON time is 70 μs (such that the duration for which the bias is in an ON state in a period is 70 μs) and a pulse OFF time is 30 μs (such that the duration for which the bias is in an OFF state in a period is 30 μs), the duty cycle is 70%.

Note that since etching is performed using the patterned mask as a mask, the aspect ratio of the gaps between the features remains the same.

Returning to FIG. 2, in an operation 209, the pattern is transferred to the carbon material using the doped tungsten-containing mask. Etching may be performed using an oxygen-containing gas mixed with a sulfur dioxide or carbon oxysulfide gas, and one or more inert gases such as nitrogen, argon, and helium. During etch, where the patterned mask is removed prior to transferring the pattern to the carbon material, no silicon is present during etching such that there is no redeposition or formation of silicon-containing residues. The etch rate of the amorphous carbon layer may be about 50 nm per minute to greater than about 1 micron per minute. The etch rate of boron-doped tungsten may be about 1 nm per minute to about 50 nm per minute.

In some embodiments, etching using certain disclosed embodiments involves etching features that have specific ellipticity as evaluated from a top view perspective of the film, e.g., by looking top down directly onto the surface of the substrate. In some embodiments, using the doped tungsten-containing mask for etching the amorphous carbon results in amorphous carbon having features that have an ellipticity of about 1 to about 1.05 or about 1 to about 1.1.

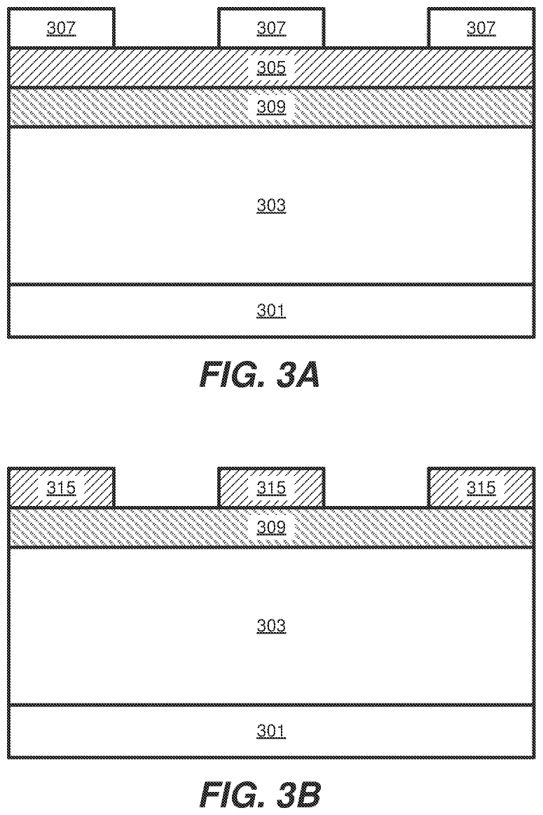

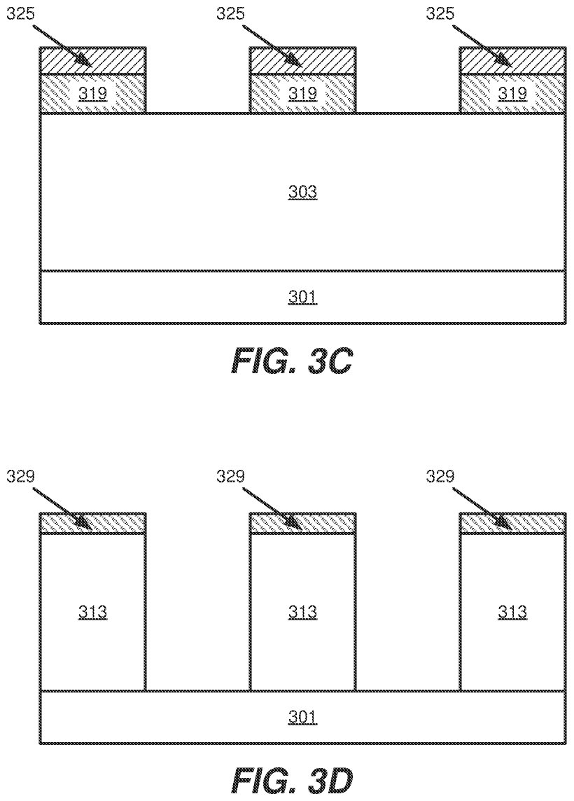

FIGS. 3A-3D show an example shows an example schematic illustration of a substrate 301 with an amorphous carbon layer 303, doped tungsten-containing layer 309, BARC layer 305, and developed photoresist 307. Although not shown, deposition of the doped tungsten-containing layer 305 on the amorphous carbon layer 303 may involve depositing an adhesion layer (not shown) directly on the amorphous carbon layer 303 followed by depositing the doped tungsten-containing layer 305. In some embodiments, developed photoresist 307 may represent a mask formed using lithographic techniques.

FIG. 3B shows a patterned BARC layer 315 after etching the BARC layer 305 in FIG. 3A using the developed photoresist 307 as a mask, using selective etching relative to the doped tungsten-containing layer 309. Such etching of the BARC layer 305 may be performed by plasma etching using the patterned resist as a mask.

FIG. 3C shows the doped tungsten-containing layer 309 in FIG. 3B is etched selectively relative to the patterned BARC layer 325 to form patterned doped tungsten-containing mask 319. In some embodiments, etching is selective only to the BARC layer and not the amorphous carbon 303 such that some amorphous carbon 303 may be etched. However, since such etching may be fairly slow, such etching is not used to fully etch the entire amorphous carbon layer and another etching chemistry, further described below, is used to etch the thickness of the amorphous carbon layer. Note that since etching is performed using the patterned BARC layer 325 as a mask, the aspect ratio of the gaps between the features remains the same. The etching chemistry is selective to etch largely the doped tungsten-containing layer 309, without etching the patterned BARC layer 325 and without substantially etching the amorphous carbon 303. In some embodiments, some very little amount of patterned BARC layer 325 may be consumed during this operation. The etching chemistry includes a halogen-containing chemistry. The etch selectivity of the metal-doped tungsten-containing layer relative to the carbon material may be at least about 10:1, or between about 30:1 and about 40:1.

FIG. 3D shows a substrate 301 with patterned carbon layer 313 etched using the patterned BARC layer 325, which has been consumed, and doped tungsten-containing mask 329 as a mask. Since the doped tungsten-containing mask is used instead of a silicon-containing mask, the amount of silicon-containing residues left at the tops of the features is reduced or, in some embodiments, completely eliminated.

Certain disclosed embodiments are also suitable for forming doped tungsten-containing spacer material. For example, doped tungsten-containing spacers may have better profile control, may reduce line bending or leaning, reduce core damage from spacer deposition, and reduce spacer etch gouging to underlying etch stop material.

### APPARATUS

Disclosed embodiments may be performed in any suitable etching chamber or apparatus, available from Lam Research Corporation of Fremont, CA. Further description of plasma etch chambers may be found in U.S. Pat. Nos. 6,841,943 and 8,552,334, which are herein incorporated by reference in their entireties.

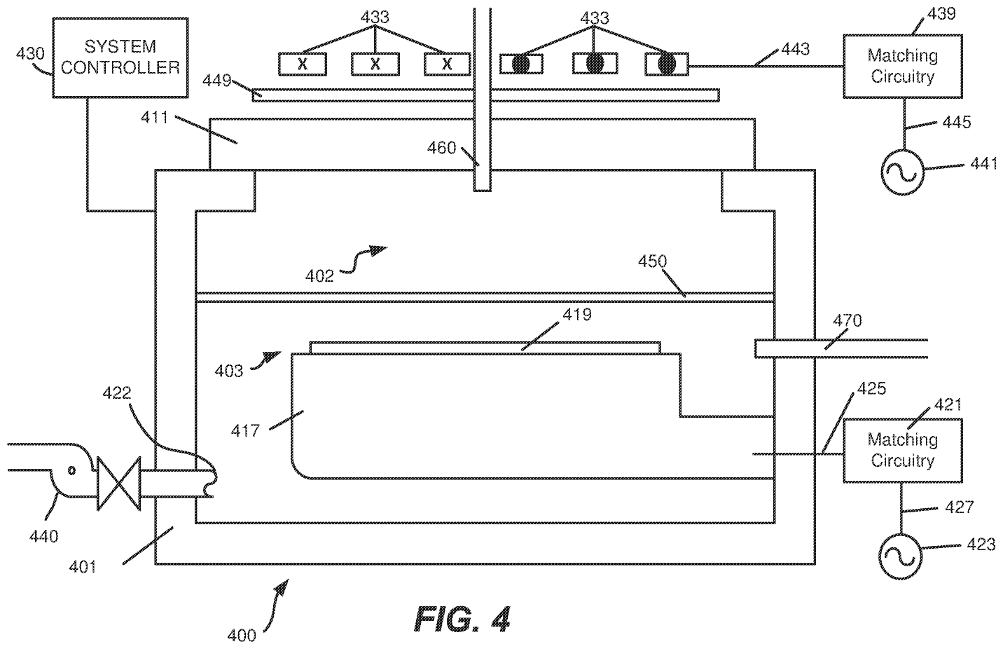

Disclosed embodiments are performed in an inductively coupled plasma (ICP) reactor. One example is provided in FIG. 4. Such ICP reactors have also been described in U.S. Pat. No. 9,362,133 issued Jun. 7, 2016, filed Dec. 10, 2013, and titled “METHOD FOR FORMING A MASK BY ETCHING CONFORMAL FILM ON PATTERNED ASHABLE HARDMASK,” hereby incorporated by reference for the purpose of describing a suitable ICP reactor for implementation of the techniques described herein. Although ICP reactors are described herein, in some embodiments, it should be understood that capacitively coupled plasma reactors may also be used. An example chamber or apparatus may include a chamber having chamber walls, a chuck for holding a substrate or wafer to be processed which may include electrostatic electrodes for chucking and dechucking a wafer and may be electrically charged using a radio frequency (RF) power supply, an RF power supply configured to supply power to a coil to generate a plasma, and gas flow inlets for inletting gases as described herein. In some embodiments, an apparatus may include more than one chamber, each of which may be used to etch, deposit, or process substrates. The chamber or apparatus may include a system controller for controlling some or all of the operations of the chamber or apparatus such as modulating the chamber pressure, inert gas flow, plasma power, plasma frequency, reactive gas flow (e.g., etching gas, etc.), bias power, temperature, vacuum settings, and other process conditions. The chamber may also be used to deposit tungsten-containing material onto a substrate.

FIG. 4 schematically shows a cross-sectional view of an inductively coupled plasma integrated etching and deposition apparatus 400 appropriate for implementing certain embodiments herein, an example of which is an inductively coupled plasma reactor, produced by Lam Research Corp. of Fremont, CA. The inductively coupled plasma apparatus 400 includes a processing chamber 401 structurally defined by chamber walls and a window 411. The chamber walls may be fabricated from stainless steel or aluminum. The window 411 may be fabricated from quartz or other dielectric material. An optional internal showerhead 450 divides the processing chamber 401 into an upper sub-chamber 402 and a lower sub-chamber 403. The showerhead may include one hole, or may include multiple holes for delivering and distributing gases and/or plasma species to lower sub-chamber 403. In most embodiments, showerhead 450 may be removed, thereby utilizing a chamber space made of sub-chambers 402 and 403. A chuck 417 is positioned within the lower sub-chamber 403 near the bottom inner surface. The chuck 417 is configured to receive and hold a semiconductor wafer 419 upon which the etching and deposition processes are performed. The chuck 417 can be an electrostatic chuck for supporting the wafer 419 when present. In some embodiments, an edge ring (not shown) surrounds chuck 417, and has an upper surface that is approximately planar with a top surface of a wafer 419, when present over chuck 417. The chuck 417 also includes electrostatic electrodes for chucking and dechucking the wafer. A filter and DC clamp power supply (not shown) may be provided for this purpose. Other control systems for lifting the wafer 419 off the chuck 417 can also be provided. The chuck 417 may be movable along an axis substantially parallel to the sidewalls of the chamber whereby the surface of the chuck 417 is substantially parallel to the ground. If a showerhead is used, the distance between the wafer 419 and the showerhead (not shown) may be between about 0.5 inches and about 3.0 inches. The chuck 417 can be electrically charged using an RF power supply 423. The RF power supply 423 is connected to matching circuitry 421 through a connection 427. The matching circuitry 421 is connected to the chuck 417 through a connection 425. In this manner, the RF power supply 423 is connected to the chuck 417.

Elements for plasma generation include a coil 433 is positioned above window 411. In various embodiments, a coil is not used in disclosed embodiments. The coil 433 is fabricated from an electrically conductive material and includes at least one complete turn. The example of a coil 433 shown in FIG. 4 includes three turns. The cross-sections of coil 433 are shown with symbols, and coils having an “X” extend rotationally into the page, while coils having a “⋅” extend rotationally out of the page. Elements for plasma generation also include an RF power supply 441 configured to supply RF power to the coil 433. In general, the RF power supply 441 is connected to matching circuitry 439 through a connection 445. The matching circuitry 439 is connected to the coil 433 through a connection 443. In this manner, the RF power supply 441 is connected to the coil 433. An optional Faraday shield 449 is positioned between the coil 433 and the window 411. The Faraday shield 449 is maintained in a spaced apart relationship relative to the coil 433. The Faraday shield 449 is disposed immediately above the window 411. The coil 433, the Faraday shield 449, and the window 411 are each configured to be substantially parallel to one another. The Faraday shield may prevent metal or other species from depositing on the dielectric window of the processing chamber 401.

Process gases (e.g. oxygen-containing gases, halogen-containing gases, doped tungsten-containing layer deposition precursors, etc.) may be flowed into the processing chamber 401 through one or more main gas flow inlets 460 positioned in the upper chamber 402 and/or through one or more side gas flow inlets 470. Likewise, though not explicitly shown, similar gas flow inlets may be used to supply process gases to a capacitively coupled plasma processing chamber. A vacuum pump, e.g., a one or two stage mechanical dry pump and/or turbomolecular pump 440, may be used to draw process gases out of the processing chamber 401 and to maintain a pressure within the processing chamber 401. For example, the pump may be used to evacuate the processing chamber 401 to remove volatile by-products generated from etching doped tungsten-containing material and undoped tungsten-containing material as well as patterned mask material such as BARC material. A valve-controlled conduit may be used to fluidically connect the vacuum pump to the processing chamber 401 so as to selectively control application of the vacuum environment provided by the vacuum pump. This may be done employing a closed-loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus, one or more process gases may be supplied through the gas flow inlets 460 and/or 470. In certain embodiments, process gas may be supplied only through the main gas flow inlet 460, or only through the side gas flow inlet 470. In some cases, the gas flow inlets shown in the figure may be replaced more complex gas flow inlets, one or more showerheads, for example. The Faraday shield 449 and/or optional grid 450 may include internal channels and holes that allow delivery of process gases to the processing chamber 401. Either or both of Faraday shield 449 and optional grid 450 may serve as a showerhead for delivery of process gases. In some embodiments, a liquid vaporization and delivery system may be situated upstream of the processing chamber 401, such that once a liquid reactant or precursor is vaporized, the vaporized reactant or precursor is introduced into the processing chamber 401 via a gas flow inlet 460 and/or 470.

Radio frequency power is supplied from the RF power supply 441 to the coil 433 to cause an RF current to flow through the coil 433. The RF current flowing through the coil 433 generates an electromagnetic field about the coil 433. The electromagnetic field generates an inductive current within the upper sub-chamber 402. The physical and chemical interactions of various generated ions and radicals with the wafer 419 selectively etch features of and deposit layers on the wafer.

If the plasma grid is used such that there is both an upper sub-chamber 402 and a lower sub-chamber 403, the inductive current acts on the gas or gases present in the upper sub-chamber 402 to generate an electron-ion plasma in the upper sub-chamber 402. The optional internal plasma grid 450 limits the amount of hot electrons in the lower sub-chamber 403. In some embodiments, the apparatus is designed and operated such that the plasma present in the lower sub-chamber 403 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower-sub-chamber 403 through port 422. The chuck 417 disclosed herein may operate at elevated temperatures ranging between about 200° C. and about 500°° C. The temperature will depend on the process operation and specific recipe.

Processing chamber 401 may be coupled to facilities (not shown) when installed in a clean room or a fabrication facility. Facilities include plumbing that provide processing gases, vacuum, temperature control, and environmental particle control. These facilities are coupled to processing chamber 401, when installed in the target fabrication facility. Additionally, processing chamber 401 may be coupled to a transfer chamber that allows robotics to transfer semiconductor wafers into and out of processing chamber 401 using typical automation.

In some embodiments, a system controller 430 (which may include one or more physical or logical controllers) controls some or all of the operations of a processing chamber. The system controller 430 may include one or more memory devices and one or more processors. In some embodiments, the apparatus includes a switching system for controlling flow rates and durations when disclosed embodiments are performed. In some embodiments, the apparatus may have a switching time of up to about 500 ms, or up to about 750 ms. Switching time may depend on the flow chemistry, recipe chosen, reactor architecture, and other factors.

The processing chamber 401 or apparatus may include a system controller. For example, in some embodiments, a controller 430 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 430, depending on the processing specification and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 430 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 430, in some implementations, may be a part of or coupled to a computer that is integrated with, coupled to the system, otherwise networked to the system, or a combination thereof. For example, the controller 430 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 430 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

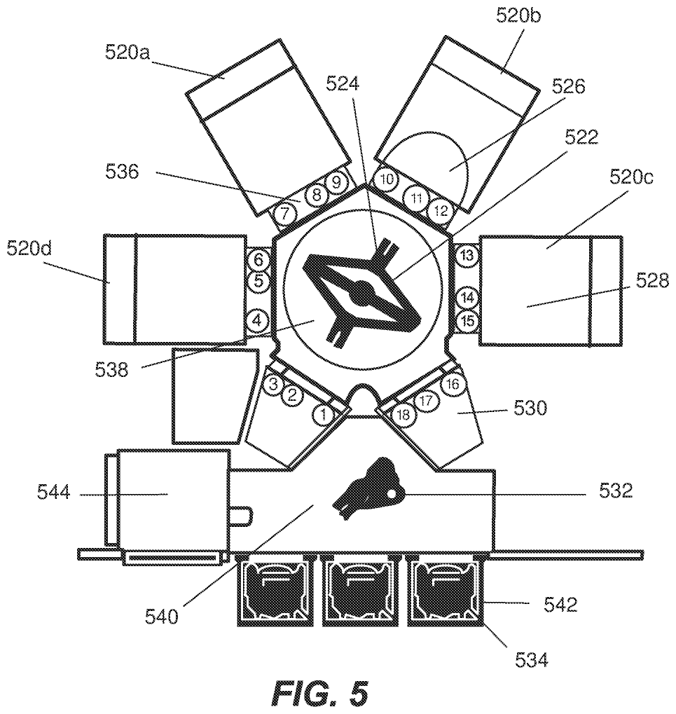

The processing chamber 401 may be integrated in a multi-station tool such as shown in FIG. 5. Each station may be used to process different operations. For example, one station may be used to perform pre-oxidation while another station is used to perform selective etching of the doped tungsten-containing material. Disclosed embodiments may be performed without breaking vacuum and may be performed in the same apparatus.

FIG. 5 depicts a semiconductor process cluster architecture with various modules that interface with a vacuum transfer module (VTM) 538. The arrangement of transfer modules to “transfer” wafers among multiple storage facilities and processing modules may be referred to as a “cluster tool architecture” system. Airlock 530, also known as a loadlock or transfer module, is shown in VTM 538 with four processing modules 520a-520d, which may be individual optimized to perform various fabrication processes. By way of example, processing modules 520a-520d may be implemented to perform substrate etching, deposition, ion implantation, wafer cleaning, sputtering, and/or other semiconductor processes. One or more of the substrate etching processing modules (any of 520a-520d) may be implemented as disclosed herein, i.e., for performing pre-oxidation, selectively removing doped tungsten-containing material, and other suitable functions in accordance with the disclosed embodiments. Airlock 530 and process module 520 may be referred to as “stations.” Each station has a facet 536 that interfaces the station to VTM 538. Inside each facet, sensors 1-18 are used to detect the passing of wafer 526 when moved between respective stations.

Robot 522 transfers wafer 526 between stations. In one embodiment, robot 522 has one arm, and in another embodiment, robot 522 has two arms, where each arm has an end effector 524 to pick wafers such as wafer 526 for transport. Front-end robot 532, in atmospheric transfer module (ATM) 540, is used to transfer wafers 526 from cassette or Front Opening Unified Pod (FOUP) 534 in Load Port Module (LPM) 542 to airlock 530. Module center 528 inside process module 520 is one location for placing wafer 526. Aligner 544 in ATM 540 is used to align wafers.

In an exemplary processing method, a wafer is placed in one of the FOUPs 534 in the LPM 542. Front-end robot 532 transfers the wafer from the FOUP 534 to an aligner 544, which allows the wafer 526 to be properly centered before it is etched or processed. After being aligned, the wafer 526 is moved by the front-end robot 532 into an airlock 530. Because airlock modules have the ability to match the environment between an ATM and a VTM, the wafer 526 is able to move between the two pressure environments without being damaged. From the airlock module 530, the wafer 526 is moved by robot 522 through VTM 538 and into one of the process modules 520a-520d. In order to achieve this wafer movement, the robot 522 uses end effectors 524 on each of its arms. Once the wafer 526 has been processed, it is moved by robot 522 from the process modules 520a-520d to an airlock module 530. From here, the wafer 526 may be moved by the front-end robot 532 to one of the FOUPs 534 or to the aligner 544.

The computer controlling the wafer movement can be local to the cluster architecture, or can be located external to the cluster architecture in the manufacturing floor, or in a remote location and connected to the cluster architecture via a network. A controller as described above with respect to FIG. 4 may be implemented with the tool in FIG. 5.

### EXPERIMENTAL

### Experiment 1

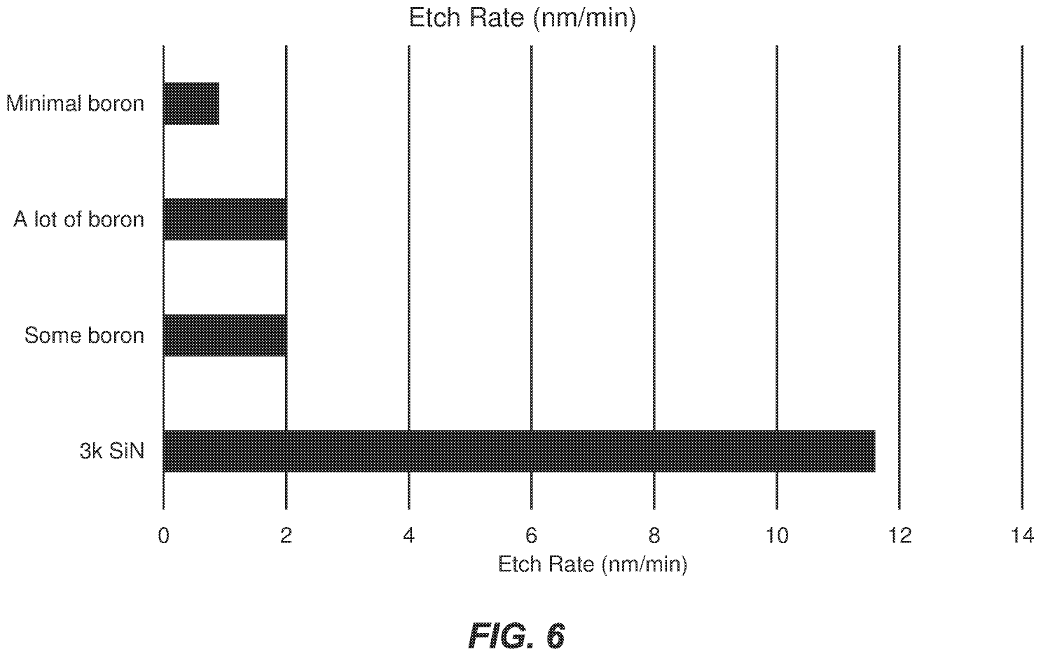

An experiment was conducted that measured etch rate of different mask materials using the same etch chemistry to etch amorphous carbon material. Three masks included boron-doped tungsten having various amounts of boron dopant and a fourth mask was a silicon nitride mask. Having minimal boron dopant in the boron-doped tungsten mask improved selectivity by 12.9 times compared to using silicon oxynitride as a mask. Using boron-doped tungsten at varying amounts of boron achieved a selectivity improvement by at least 5.8 times that of a SiON mask as shown in FIG. 6.

### Experiment 2

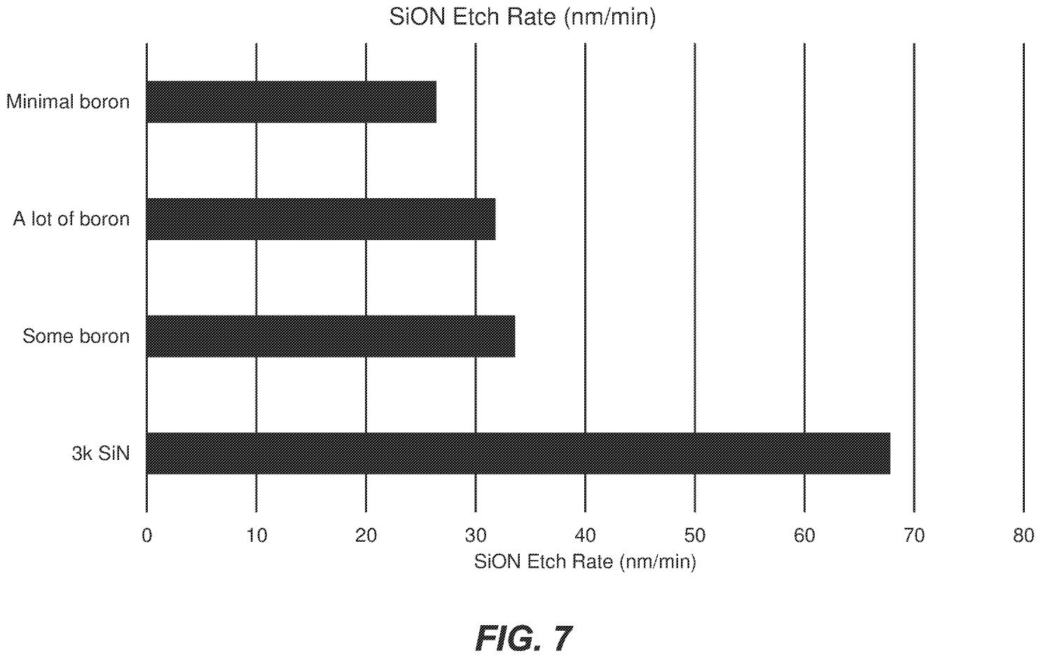

An experiment was conducted that measured etch rate of boron-doped tungsten-containing material using SiN etching chemistry. Boron-doped tungsten had a lower etch rate relative to SiON, by at least a 52% reduction as shown in FIG. 7. FIGS. 6 and 7 suggest that boron-doped tungsten-containing material can be used as a mask material for amorphous carbon material with high selectivity relative to a SiN-based mask (FIG. 6) and the boron-doped tungsten-containing material can be easily etched using SiN etch chemistry (FIG. 7), making it a better mask material than SiON.

### Experiment 3

An experiment was conducted that tested adhesion strength as adhesion layer deposition temperature and adhesion layer diborane flow were varied. On one substrate, an adhesion layer was deposited using 90 sccm of diborane using an apparatus having stations having a temperature of 250° C. and 325° C. The adhesion layer was of poor quality and was easily peeled. On a second substrate, an adhesion layer was deposited using 190 sccm of diborane using an apparatus having stations having temperatures of 250° C. and 325° C. The adhesion layer was of better quality but some material was peelable. On a third substrate, an adhesion layer was deposited using 190 sccm of diborane using an apparatus having a station having a temperature of 325° C. The adhesion layer sustained peeling and showed highly improved adhesion strength.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a substrate comprising an amorphous carbon layer to be etched, the amorphous carbon layer having a thickness of at least about 100 nm;
forming a patterned doped tungsten-containing mask over the amorphous carbon layer; and
etching the amorphous carbon layer using the patterned doped tungsten-containing mask to form a patterned carbon-containing layer.

2. The method of claim 1, wherein the patterned doped tungsten-containing mask comprises a metal dopant, the metal dopant selected from the group consisting of boron, titanium, tungsten, tantalum, tin, aluminum, and combinations thereof.

3. The method of claim 1, wherein the amorphous carbon layer is dopant-free.

4. The method of claim 1, wherein the amorphous carbon layer comprises less than about 10% impurities.

5. The method of claim 1, further comprising prior to forming the patterned doped tungsten-containing mask, depositing an adhesion layer directly on the amorphous carbon layer.

6. The method of claim 1, wherein the patterned doped tungsten-containing mask is silicon-free.

7. The method of claim 1, wherein forming the patterned doped tungsten-containing mask comprises depositing doped tungsten-containing material and etching the doped tungsten-containing material using a photoresist mask to form the patterned doped tungsten-containing mask.

8. The method of claim 1, wherein ellipticity of features formed in the amorphous carbon layer after the etching the amorphous carbon layer is about 1 to about 1.1.

9. The method of claim 1, wherein the etching of the amorphous carbon layer is performed using one or more gases that form volatile byproducts with the patterned doped tungsten-containing mask and amorphous carbon layer without redepositing material onto substrate surfaces.

10. The method of claim 1, wherein the patterned doped tungsten-containing mask is doped with boron and the etching of the amorphous carbon layer is performed in a silicon-free environment.
